(19) United States
(12) Patent Application Publication
(10) Pub. No.: US 2006/0228543 A1
(43) Pub. Date: Oct. 12, 2006

(54) Metal/fullerene anode structure and application of same

(76) Inventors: Zheng-Hong Lu, Toronto, CA (US); Sijin Han, North York, CA (US); Yanyan Yuan, Toronto, CA (US)

Correspondence Address: Ralph A. Dowell of DOWELL & DOWELL P.C., 2111 Eisenhower Ave, Suite 406, Alexandria, VA, 22314, US

(21) Appl. No.: 11/401,463

(22) Filed: Apr. 11, 2006

Related U.S. Application Data
(60) Provisional application No. 60/670,244, filed on Apr. 12, 2005.

(51) Int. Cl. B32B 15/04; B32B 5/16; H01L 51/50; H05B 33/26

(52) U.S. Cl. 428/323; 428/336; 428/457; 977/735; 977/742; 428/690; 428/917; 313/503; 313/504; 313/506; 257/E51.019

(57) ABSTRACT

The present invention provides a layered metal/fullerene anode structure for efficient hole injection. The layered anode structure includes one or more layers of electrical conductors and a second layer containing fullerenes. The thickness of the second layer is selected so that the layered structure facilitate hole transfer from the layer to second layer under electrical bias. The present invention also provides a light-emitting device which includes a layered metal/fullerene anode. The device includes an hole transport layer, and a second electrically conductive layer defining a cathode electrode layer. The device includes a layer of light-emissive material between the hole transport layer and the cathode electrode. The device may also include a hole injection layer interposed between the layered metal/fullerene anode and the hole transport layer. The device may also include a dielectric layer attached to the metal layer of the layered metal/fullerene anode.

### CROSS REFERENCE TO RELATED APPLICATIONS

This patent application claims the priority benefit from U.S. Provisional Patent Application Ser. No. 60/670,244 filed on Apr. 12, 2005 entitled METAUFULLERENE ANODE STRUCTURE AND APPLICATION OF SAME, which is incorporated herein by reference in its entirety.

### FIELD OF THE INVENTION

The present invention relates to metal/fullerene anode structure for efficient hole injection and more particularly the present invention relates to use of metal/fullerene anode for highly efficient organic-based light-emitting devices (OLEDs), replacing the problematic metal oxides anode.

### BACKGROUND OF THE INVENTION

A typical organic light-emitting device (OLED) includes an anode, an active light-emitting zone comprising one or more electroluminescent organic material(s), and a cathode. One of the electrodes needs to be optically transmissive while the other electrode can be optically reflective. The function of the anode is to inject positively charged particles referred to as holes into the light-emitting zone, and that of the cathode is to inject electrons into the emission zone. A process involved in the recombination of the electrons and the hole leads to the creation of photons which then exit through the optically transmissive electrode.

Because of its high optical transparency and moderate electrical conductivity, Indium Tin Oxide (ITO) has been used exclusively as the standard anode layer despite many shortcomings of this material. For example, the work function of ITO is known to vary dramatically depending on surface treatment method and conditions (H. Y. Yu, X. D. Feng, D. Grozea, Z. H. Lu, R. N. S. Sodhi, A-M. Hor and H. Aziz, Appl. Phys. Lett. 78, 2595 (2001)). It has been reported that various species from the ITO will diffuse into the organic semiconductor layers which leads to degradation in device performance (P. Melpignano, A. Baron-Toaldo, V. Biondo, S. Priante, R. Zamboni, M. Murgia, S. Caria, L. Gregoratti, A. Barinov, and M. Kiskinova, Appl. Phys. Lett. 86, 041105 (2005)). The use of ITO is also limited because of its deposition and post-deposition annealing require temperatures in excess of 200° C., which may, for example, exclude the use of flexible plastic substrates in a roll-to-roll type fabrication process. The resisitivity of ITO is typically of the order of 10⁻⁴Ω·cm, which is two orders of magnitude higher than that of typical metals. This leads to significant voltage drops across the ITO electrode and hence power loss and non-uniformity in light output. Thus, an alternative electrically conductive anode to this metal oxide would be very desirable for OLEDs in applications which require high-power, large surface area displays and ease in manufacturing.

As a family member of naturally occurring allotropes of carbon, fullerene materials are known for their robust structures and superior charge transport properties. U.S. Pat. No. 5,861,219 discloses the use of fullerenes as a dopant added to a host metal complex of 5-hydroxy-quinoxaline used in organic light emitting diodes. The host metal complex of 5-hydroxy-quinoxaline is contained in the electroluminescent layer which forms the emission zone in the structure. United States Patent Publication US 2002/0093006 A1 discloses the use of a fullerene layer as the light emissive layer in an organic light emitting diode structure.

U.S. Pat. No. 6,853,134 discloses Au coated with a layer of thiol or thiol-derivative as the anode.

United States Patent Publication No. US2004/0140758 discloses the use of metal and metal alloy as anode.

United States Patent Publication US 2003/0042846 A1 discloses the use of a fullerene layer as an electron acceptor layer in organic photovoltaic devices.

Japan Patent 3227784 and Japanese patent application 04-144479 disclose the use of fullerenes as a hole transport layer.

U.S. Pat. No. 5,171,373 discloses the use of fullerenes in solar cells. U.S. Pat. No. 5,759,725 discloses the use of fullerenes in photoconductors.

The use of fullerenes as an interface layer between the hole transport layer and the light emission layer has been disclosed by Keizo Kato, Keisuke Suzuki, Kazunari Shinbo, Futao Kaneko, Nozomu Tsuboi, Satosh Kobayashi, Toyoyasu Tadokoro, and Shinichi Ohta, Jpn. J. Appl. Phys. Vol. 42, 2526 (2003).

Copending U.S. patent application Ser. No. 10/811,153 discloses the use of metal/LiF/fullerene structure for charge injection. The same patent application discloses the use of fullerene as an electron transport layer.

It is well-known that fullerene forms a primary bond with many metals. This interfacial fullerene layer should facilitate charge flow from a metallic system to a molecular system. It would be very advantageous to provide an organic-based electroluminescence device with better anode structures using metal/fullerene bi-layers for improved hole injection from the anode to the hole transport layer and then to the light emission zone.

### SUMMARY OF THE INVENTION

It is the objective of this invention to provide a metal/fullerene layered structure for efficient hole injection into a molecular system or thin-film device.

It is another the object of the present invention to provide an organic-based electroluminescence device in which a metal/fullerene layered structure is used as the anode, replacing the current problematic ITO anode or simple metal anode.

In one aspect of the invention there is provided a layered electrically conductive material/fullerene anode structure comprising:

a) a substrate and a first layer comprising fullerenes located on a surface of the substrate; and

b) a second layer comprising an electrically conductive material located on a top surface of said first layer, the thickness of the first layer being selected so that the layered electrically conductive material/fullerene anode structure exhibits hole injection behavior across the first and second layers.

In another aspect of the invention there is provided a light-emitting device, comprising:

a) an electrically conductive layered metal/fullerene anode electrode including a metal layer formed on a substrate and a layer including fullerenes formed on the metal layer;

b) a hole transport layer located on the fullerene layer;

c) a layer of electroluminescent material located on the hole transport layer; and

d) an electrically conductive layer defining a cathode electrode layer on the layer of a electroluminescent material, and wherein one or both of the electrically conductive layered metal/fullerene anode electrode and the cathode electrode layer is semi-transparent so that the light emitted from the layer of electroluminescent material exits the device.

A further understanding of the functional and advantageous aspects of the invention can be realized by reference to the following detailed description and drawings.

### BRIEF DESCRIPTION OF THE DRAWINGS

The layered metal/fullerene anode structure and the light-emitting device produced according to the present invention will now be described, by way of example only, reference being made to the accompanying drawings, in which:

FIG. 1 is a sectional view of a layered metal/fullerene anode structure produced in accordance with the present invention;

FIG. 2 is a schematic cross sectional view of a light-emitting device constructed in accordance with the present invention;

FIG. 3 is a plot of current versus voltage relationship for an OLED with Au/C60 anode constructed according to FIG. 2 using a reference OLED device with Au anode. The device was constructed in the following stacking sequence: glass substrate/Anode/HIL/HTL/EL/ETL/cathode. The materials for HIL (hole injection layer), HTL (hole transport layer), EL (emission layer), ETL (electron transport layer) and cathode are CuPc [copper phthalocyanine] (15 nm), NPB [N, N′-bis (I-naphthyl)-N, N′-diphenyl-1, 1′-biphenyl-4, 4′-diamine ] (45 nm), Alq [tris (8-hydroxyquinolinato) aluminum] (25 nm), C60 (10 nm), and LiF (1.5 nm)/Al (120 nm).

FIG. 4 is a plot of luminance versus voltage relationship for an OLED with Au/C60 anode constructed according to FIG. 2 using a reference OLED device with Au anode. The device was constructed in the following stacking sequence: glass substrate/Anode/HIL/HTL/EL/ETL/cathode. The materials for HIL, HTL, EL, ETL and cathode are CuPc (15 nm), NPB (45 nm), Alq (25 nm), C60 (10 nm), and LiF (1.5 nm)/Al (120 nm).

FIG. 5 is a plot of current efficiency versus luminance relationship for OLEDs with Au/C60 and Au anode, respectively. These were the same devices as described in FIG. 3.

FIG. 6 are plots of current versus voltage relationships for organic EL devices with Au (25 nm)/C60 (dₓ nm) layered anode with the fullerene C60 thickness dₓ varied from 0 nm to 15 nm. The rest of the device structure was the same as described in FIG. 3.

FIG. 7 plots device driving voltage at constant current density of 20 mA/cm² and 100 mA/cm², as a function of fullerene C60 thickness dₓ of devices described in FIG. 6.

FIG. 8 plots current versus voltage relationship for an OLED with Au/C60 anode constructed according to FIG. 2 using a reference OLED device with Au anode. The device was constructed in the following sequence: glass substrate/Anode/HIL/HTL/EL/ETL/cathode. The materials for HIL, HTL, EL, ETL and cathode are m-MTDATA [4,4′,4″-tris(3-methylphenylphenylamino)triphenylamine] (15 nm), NPB (45 nm), Alq (25 nm), C60 (10 nm), and LiF (1.5 nm)/Al (120 nm), respectively.

Table I. Summary of device characteristics of OLEDs with various Au/fullerene anode structures. The OLEDs were constructed in the following stacking sequence: glass substrate/Anode/HIL/HTL/EL/ETL/cathode. The materials for HIL, HTL, EL and cathode are CuPc (15 nm), NPB (45 nm), Alq (25 nm) and LiF (1.5 nm)/Al (120 nm), respectively. Alq and C60 were used as ETL to test the OLED performance.

Table II. Summary of device characteristics of OLEDs with various Ag/fullerene anode structures. The OLEDs were constructed in the following stacking sequence: glass substrate/Anode/HIL/HTL/EL/ETL/cathode. The materials for HIL, HTL, EL and cathode are CuPc (15 nm), NPB (45 nm), Alq (25 nm) and LiF (1.5 nm)/Al (120 nm), respectively. Alq and C60 were used as ETL to test the OLED performance.

Table III. Summary of device characteristics of inverted top-emission OLEDs with various Ag/fullerene anode structures. The OLEDs were constructed in the following stacking sequence: ubstrate/cathode/ETL/EL/HTL/HIL/Anode. The materials for HIL, HTL, EL and cathode are CuPc (15 nm), NPB (45 nm), Alq (25 nm) and LiF (1.5 nm)/Al (75 nm), respectively. Alq and C60 were used as ETL to test the OLED performance.

Table IV. Summary of device characteristics of inverted top-emission OLEDs with various Au/fullerene anode structures. The devices were constructed in the following stacking sequence: substrate/cathode/ETL/EL/HTL/HIL/Anode. The materials for HIL, HTL, EL and cathode are CuPc (15 nm), NPB (45 nm), Alq (25 nm) and LiF (1.5 nm)/Al (120 nm), respectively. Alq and C60 were used as ETL to test the OLED performance.

Table V. Summary of device characteristics of OLEDs with various Au/fullerene anode structures. Here the fullerene layer is a mixture of C60 and CuPc with various C60 concentration varied from 0 wt. % to 100 wt. %. The OLEDs were constructed in the following stacking sequence: glass substrate/Anode/HIL/HTL/EL/ETL/cathode. The materials for HIL, HTL, EL, ETL and cathode are CuPc (15 nm), NPB (45 nm), Alq (25 nm), Alq (15 nm) and LiF (1 nm)/Al (100 nm), respectively.

Table VI. Summary of device characteristics of OLEDs with various Ag/fullerene anode structures. Here the fullerene layer is a mixture of C60 and CuPc with various C60 concentration varied from 0 wt. % to 50 wt. %. The OLEDs were constructed in the following stacking sequence: glass substrate/Anode/HIL/HTL/EL/ETL/cathode. The materials for HIL, HTL, EL, ETL and cathode are CuPc (15 nm), NPB (45 nm), Alq (25 nm), Alq (15 nm) and LiF (1 nm)/Al (100 nm), respectively.

Table VII. Summary of device characteristics of OLEDs with Au:C60 anode. The OLEDs were constructed follows a stacking sequence: glass substrate/Au:C60 Anode/HTL/EL/ETL/cathode. The materials for HTL, EL, ETL and cathode are CuPc (25 nm)/NPB (45 nm), Alq (25 nm), Alq (15 nm) and LiF (1.5 nm)/Al (100 nm), respectively.

### DETAILED DESCRIPTION OF THE INVENTION

Definitions

As used herein, the phrase “electron transport layer (ETL)” means a thin-film material having a primary function of conducting or transporting electrons across the layer from one region to another region.

As used herein, the phrase “hole transport layer (HTL)” means a thin-film material having a primary function to conduct holes across the layer from one region to another region.

As used herein, the phrase “light emissive layer” or “light-emission layer” means a thin-film material having the primary function of emitting light.

As used herein, the phrase “electroluminescence layer (EL)” means a thin-film material having a primary function of emitting light under electrical stimulation.

As used herein, the phrase “hole injection layer (HIL)” means a thin-film materials having a primary function of enhance hole injection from anode to the HTL.

As used herein, the phrase “metal/fullerene anode” means a layered structure consisting of at least one layer of metal and one layer of materials containing fullerene having a primary function of hole injection.

As used herein, the term “fullerene” means nanostructured carbon consisting of 60, 70, or more carbon atoms self-bonded in spherical forms or tube form, which is also known as carbon nanotubes. The carbon atoms may be bonded to additional atoms or functional groups.

As used herein, the phrase “carbon nanotubes” means carbon atoms bonded to each other in a honeycomb structure rolled into a cylinder

As used herein, the phrase “highly conductive organic molecules or polymers” means materials in which single, double or triple bonds alternate throughout the molecule or polymer and are capable of conducting charge when packed in a solid state form.

As used herein, the phrase “cathode capping layer” means an over coating film to protect the cathode from being oxidized.

As used herein, the phrase “OLEDs” means organic light-emitting diodes.

As used herein, the phrase “interfacial contact layer”, or “interfacial layer” means an ultra-thin layer inserted between two adjacent layers to serve as an interface transition layer.

As used herein, the phrase CuPc means copper phthalocyanine; NPB means N, N′-bis (I-naphthyl)-N, N′-diphenyl-1, 1′-biphenyl-4, 4′-diamine; m-MTDATA means 4,4′,4″-tris(3-methylphenylphenylamino)triphenylamine; and Alq means tris (8-hydroxyquinolinato) aluminum.

Layered Metal/Fullerene Anode Structure

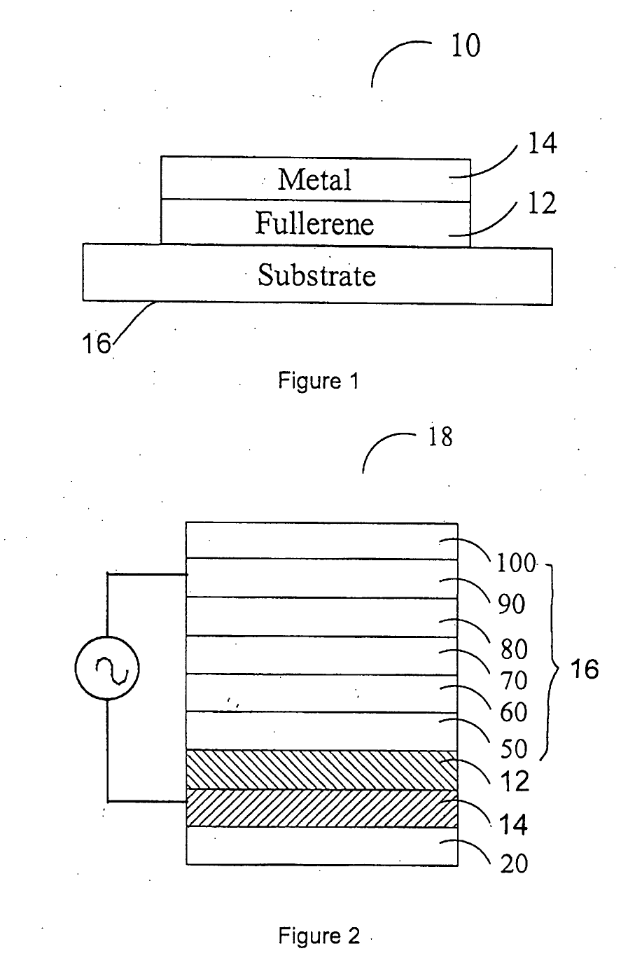

Referring first to FIG. 1 there is shown a layered metal/fullerene structure 10. The anode structure 10 comprises a substrate 16, a fullerene layer 12 contacting formed on substrate 16 and a metal layer 14 on top of the fullerene layer 12.

The fullerenes in layer 12 are preferably C60, C70, carbon nanotubes or any combination thereof. The fullerene layer 12 may also be a mixed layer comprising fullerenes and one or more organic molecules or polymers. The preferred organic molecules are CuPc and m-MTDATA. The metal layer 14 may for example be one of, but not limited to, Al, Cr, Cu, Ag, Au, Ni, Fe, Ni, W, Mo, Co and metal alloys. The metal layer 14 may also be a mixed layer comprising fullerenes and layers of one or more metals, and/or metal oxides such as, but not limited to, Cr/Au, Ag/Au, Cr/Ag, Cr/Pt, Cr/Ni, Cr/Ag/Au, Cr/Cu/Au, ITO/Au, ITO/Ag, Si/SiO₂/Au, and Si/SiO₂/Ag.

The substrate 16 of device 10 is a hole transport layer of an optoelectronic device such as OLEDs, photodetectors, photosensors, solar cells, tunneling diodes and solid-state lasers. For example, substrate 16 may be a thin-film field-effect transistor. The primary function of device 10 is to provide efficient hole conductance between layer 14 and the device represented by substrate 16. The case studies will be provided in current vs voltage characteristics of various OLEDs in the following text.

Electroluminescent Device

Referring to FIG. 2, an EL device 18 has been constructed to demonstrate the integration of the layered metal/fullerene anode 10 of FIG. 1 into a typical small organic molecule based device of the type disclosed in U.S. Pat. No. 4,356,429. The device 18 comprises a substrate 20 on which is formed the layered anode structure comprising the metal layer 14 and fullerene layer 12. The rest of the device (corresponding to substrate 16 of FIG. 1), includes a hole injection layer 50 for enhanced injection formed on fullerene layer 12, and a hole transport layer 60 for hole transport formed on layer 50, a light emissive or light-emission layer 70 capable of emitting light formed on the hole transport layer 60, an electron transport layer 80 formed on the light-emission layer 70, and a conductive cathode layer 90 formed on layer 80. An optional cathode capping layer 100 made of a dielectric, such as Si oxides or nitrides, may be deposited on the cathode layer 90.

In another embodiment of the invention device 18 may include a dielectric layer interposed between the metal layer 14 and the substrate 20. The dielectric layer may be selected to promote adhesion between layer 14 and substrate 20. The dielectric layer may also selected as an optical coupling layer to enhance optical transmission between layer 14 and substrate 20. The dielectric layer may be a phosphor, which can be readily excited by light emitted from the emissive layer 70. The light emitted from the excited phosphor layer, when combined with the light emitted from layer 70, renders device 18 a broadband light emitter.

Substrate 20 may be a glass or alternatively it could be made of any material capable of providing mechanical support to thin films. It could be coated with functional thin-film transistors which may be used as electrical drivers depending on the purpose of the layered device 18. Substrate 20 may be optically transparent for light emitted from the light emissive layer 70. Alternatively, layers 90 and 100 may be made of suitable materials and thickness to ensure light is coupled out of the light emissive layer 70 through these layers.

The conductive layered metal/fullerene anode layer 12/14 is a hole injection electrode, as described with reference to the structure in FIG. 1, when a positive potential bias is applied to it. As mentioned with respect to the layered structure of FIG. 1, the metal electrode layer 14 is may be a metal or metal alloy with a high work function >4 eV such as for example Au, Ag, Pt, Ni, Cr, Mo, W, or it may be a mixed layer comprising fullerenes and one or more metals. The fullerene layer 12 may be C60, C70, carbon nanotubes, or a mixture thereof. Beside fullerenes, the fullerene layer 12 of the metal/fullerene anode may be selected from a mixture of fullerenes with highly conductive organic molecules or polymers such as CuPc and PPV.

In the present invention, the EL layer 70 is placed between the metal/fullerene anode layers 14/12 and a metal cathode layer 90. One or both of the electrodes has to be semi-transparent so that the light emitted from the EL layer 70 can escape the device. For a conventional bottom emission OLED structure, the metal/fullerene anode structure 14/12 needs to be semi-transparent and the cathode layer 90 is preferably reflective. This restricts the thickness of the anode metal layer 14 to be less than 30 nm. On the other hand, for a top emission OLED structure, the metal/fullerene anode layer 14 should be highly reflective and the cathode metal layer 90 needs to be at least semi-transparent. In this case, a metal/metal bilayer such as Cr/Au can be used to render the anode highly reflective. For some applications both anode and cathode may be semi-transparent so that the emitted light from the EL layer can be observed from either side of the device.

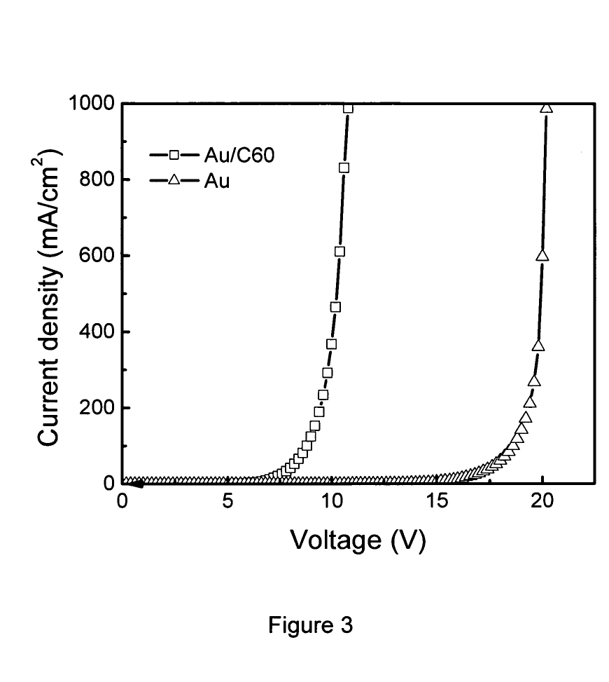

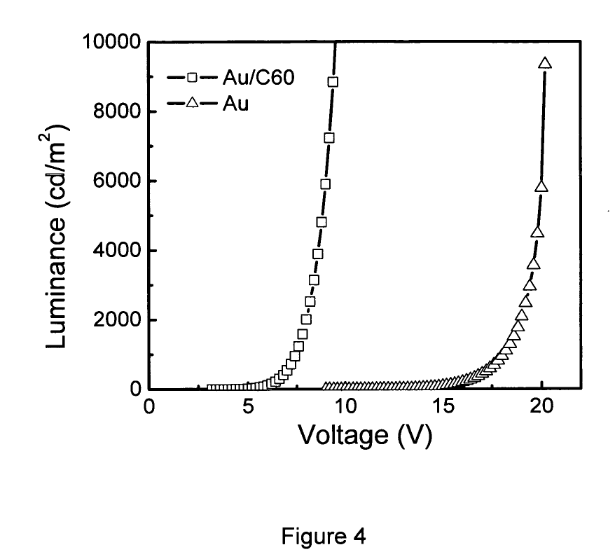

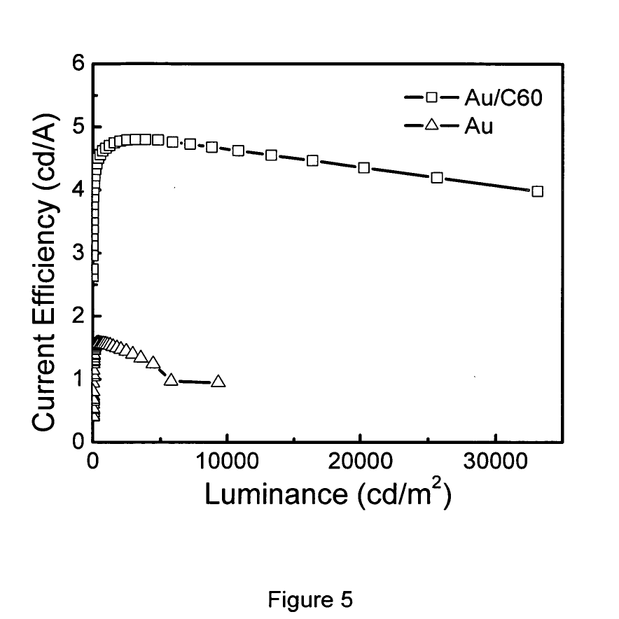

FIG. 3 and FIG. 4 demonstrate the effectiveness of Au/C60 anode in an OLED. As compared with OLED with pure Au anode, the driving voltage of OLED with Au/C60 anode is reduced by about 10 V. Furthermore, FIG. 5 shows that the current efficiency is significantly increased when Au/C60 anode is applied to a standard OLED. Table I summarizes the device characteristics of an Au/C60 anode and Au anode with two different types of electron transport layer (ETL). Table II summarizes the device characteristics of Ag/C60 anode and Ag anode with two different types of electron transport layer (ETL). It is quite obvious that these test data prove the superior performance of OLED with metal/fullerene anode over traditional OLED with a simple metal anode.

Table III summarizes the device characteristics of Ag/C60 anode applied to inverted top-emission OLEDs tested with two different types of electron transport layer (ETL).

Table IV summarizes the device characteristics of Au/C60 anode applied to inverted top-emission OLEDs tested with two different types of electron transport layer (ETL).

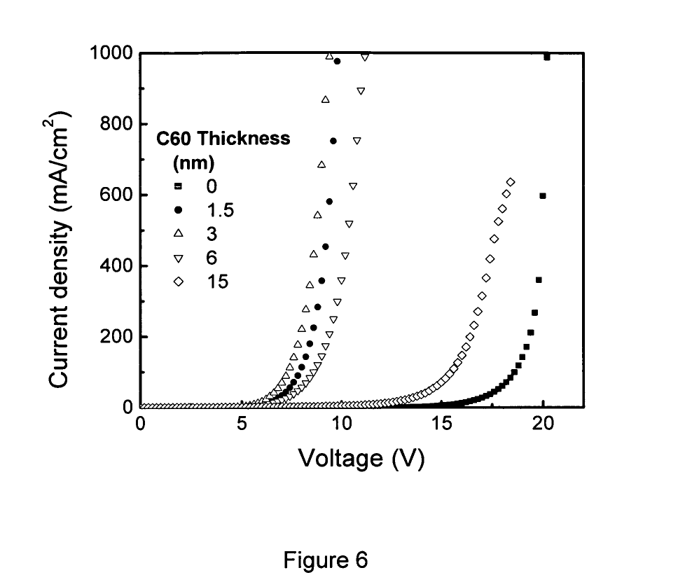

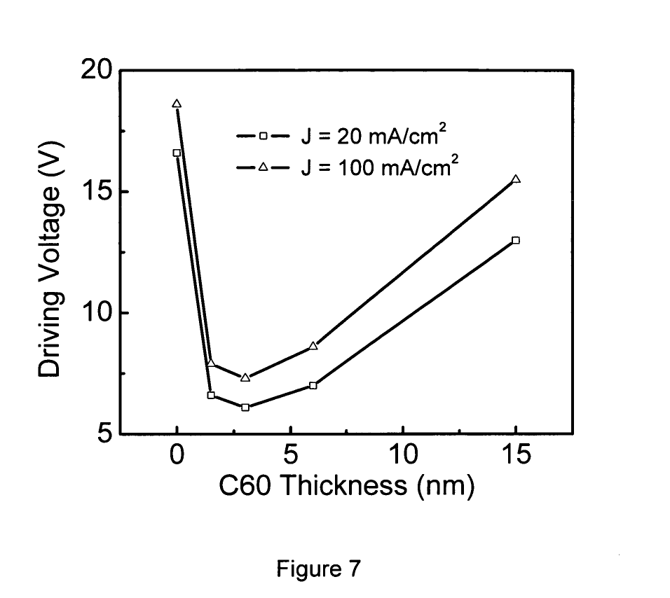

FIG. 6 shows device characteristics of various OLEDs constructed using various types of Au/C60 anodes where the thickness of the C60 layer is varied from 0 nm to 15 nm. FIG. 7 plots the driving voltage as a function of C60 thickness under two fixed current conditions. The data indicate that the preferred C60 thickness is in a range from about 1 nm to about 5 nm.

Table V summarizes the device characteristics of Au/C60:CuPc anode with various C60 mix ratio of the C60:CuPc mixture varied from 0 wt. % to 100 wt. %. The data indicate preferred C60 mix ratio is about 30 wt. %.

Table VI summarizes the device characteristics of Ag/C60:CuPc anode with various C60 mix ratio of the C60:CuPc varied from 0 wt. % to 50 wt. %. The data indicate the preferred C60 mix ratio is about 30 wt. %.

Table VII. Summarizes the device characteristics of OLEDs with Au:C60 anode. The OLEDs were constructed follows a stacking sequence: glass substrate/Au:C60 Anode/HTL/EL/ETL/cathode. The materials for HTL, EL, ETL and cathode are CuPc (25 nm)/NPB (45 nm), Alq (25 nm), Alq (15 nm) and LiF (1.5 nm)/Al (100 nm), respectively. The data indicate that C60 doped Au anode is advantageous over a simple Au anode in terms of device operating voltage.

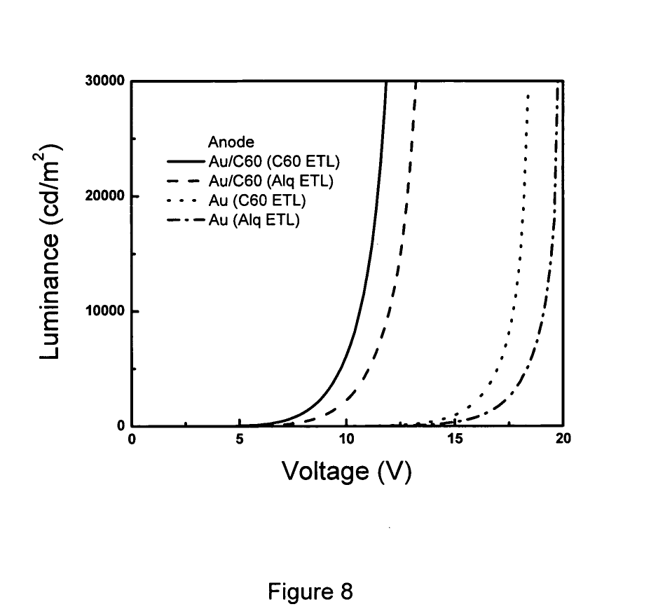

A preferred material for hole injection layer 50 is a highly conductive molecule such as CuPc. Other preferred hole injection molecules should have the following characteristics: high hole mobility, good film forming capability with the fullerene surfaces. Other preferred hole injection molecules include other forms of phthalocyanine or m-MTDATA. FIG. 8 shows that the driving voltage of OLEDs with m-MTDATA is dramatically reduced when Au/C60 anode is applied.

Hole transport layer (HTL) 60 is preferably an organic-based layer and may be NPB which is commonly used as the HTL, and may have a thickness of about, but not limited to, 60 nm. It could also be any other one or more layers of organic or polymer materials capable of transporting holes and having a thickness range from about 10 nm to about 300 nm. The hole-transport layer 60 may be comprised of those materials disclosed in United States Patent Publication No. 20020180349 which is Ser. No. 10/117,812 published Dec. 5, 2002 which is incorporated herein by reference in its entirety, which application refers to U.S. Pat. Nos. 4,539,507; 5,151,629; 5,150,006; 5,141,671 and 5,846,666 which are all incorporated herein by reference in their entirety. This reference discloses different hole transport layer materials, electron transport layer materials, anode materials and cathode materials, which application refers to U.S. Pat. Nos. 4,539,507, 5,942,340 and 5,952,115 which are all incorporated herein by reference in their entirety.

Light emissive or light-emission layer 70 may be an organic electroluminescence layer comprised of, for example, tris-(8-hydroxyquinoline) aluminum (Alq) and may have a thickness of 25 nm. It could also be a layer of an organic compound capable of emitting different colors and having a thickness in the range from about 10 nm to about 100 nm. Other suitable materials useful for the light emission-layer include conjugated polymers such as poly (paraphenylene vinylene) (PPV); various members of PPV with and without pigment dyes such as disclosed in U.S. Pat. Nos. 5,294,869 and 5,151,629; rare earth metal, actinide or transition metal organic complex as disclosed in U.S. Pat. No. 6,524,727, all being incorporated herein by reference.

The light-emission layer 70 region can also include any one or a mixture of two or more of fluorescent and phosphorescent materials including small molecules and polymers. For example, the light-emission layer 70 may be comprised of those materials disclosed in United States Patent publication 20020180349. U.S. patent application Ser. Nos. 08/829,398; 09/489,144 and U.S. Pat. No. 6,057,048 also disclose materials which may be used for the light-emission layer 70 and these references are incorporated herein in their entirety.

Electron transport layer 80 is preferably comprised of the fullerene compound C60 and has a thickness range from about 1 nm to about 300 nm, and more preferably from about 1 nm to 120 nm. Other electron transport materials include Alq and other organic compounds capable of transporting electrons.

The cathode layer 90 is preferably a LiF/Al bi-layer. It may be selected from other low work function metals or metal alloys such as Ca, Mg, Mg:Ag and Li:Al to mention just a few.

Capping layer 100 made of a dielectric, such as Si oxides and nitrides, may be deposited on the cathode by sputtering or any of the other coating techniques known to those skilled in the art.

As used herein, the terms “comprises”, “comprising”, “including” and “includes” are to be construed as being inclusive and open ended, and not exclusive. Specifically, when used in this specification including claims, the terms “comprises”, “comprising”, “including” and “includes” and variations thereof mean the specified features, steps or components are included. These terms are not to be interpreted to exclude the presence of other features, steps or components.

The foregoing description of the preferred embodiments of the invention has been presented to illustrate the principles of the invention and not to limit the invention to the particular embodiment illustrated. It is intended that the scope of the invention be defined by all of the embodiments encompassed within the following claims and their equivalents.

TABLE I
Device characteristics of OLEDs with various Au/fullerene anode structures.
The OLEDs were constructed follows a stacking sequence: glass
substrate/Anode/HIL/HTL/EL/ETL/cathode. The materials for HIL, HTL, EL and
cathode are CuPc (15 nm), NPB (45 nm), Alq (25 nm) and LiF (1.5 nm)/Al (120 nm),
respectively. Alq and C60 were used as ETL to test the OLED performance.
The luminance, driving voltage, current efficiency η_{c} (cd/A) and power
efficiency ηₚ (lm/W) were listed at two are current densities
J = 20 mA/cm² and 100 mA/cm², respectively.

| | | Luminance | | | | | | | |
|---|---|---|---|---|---|---|---|---|---|
| Device structure | | (cd/m²) | | Voltage (V) | | η_{c} (cd/A) | | ηₚ (lm/W) | |
| Anode structure (nm) | ETL (nm) | J = 20 | J = 100 | J = 20 | J = 100 | J = 20 | J = 100 | J = 20 | J = 100 |
| Au (25) | Alq (10) | 320 | 1580 | 19.1 | 21.3 | 1.60 | 1.58 | 0.26 | 0.24 |
| Au (25) | C60 (10) | 314 | 1520 | 16.6 | 18.6 | 1.57 | 1.52 | 0.30 | 0.26 |
| Au (25)/C60 (3) | Alq (10) | 1014 | 5340 | 8.8 | 10.4 | 5.07 | 5.34 | 1.81 | 1.61 |
| Au (25)/C60 (3) | C60 (10) | 932 | 4790 | 7.4 | 8.8 | 4.66 | 4.79 | 1.98 | 1.71 |

TABLE II
Device characteristics of OLEDs with various Ag/fullerene anode structures.
The OLEDs were constructed follows a stacking sequence: glass
substrate/Anode/HIL/HTL/EL/ETL/cathode. The materials for HIL, HTL, EL and
cathode are CuPc (15 nm), NPB (45 nm), Alq (25 nm) and LiF (1.5 nm)/Al (120 nm),
respectively. Alq and C60 were used as ETL to test the OLED performance.
The luminance, driving voltage, current efficiency η_{c} (cd/A) and power
efficiency ηₚ (lm/W) were listed at two are current densities
J = 20 mA/cm² and 100 mA/cm², respectively.

| Device structure | | Luminance | | | | | | | |
|---|---|---|---|---|---|---|---|---|---|
| | ETL | (cd/m²) | | Voltage (V) | | η_{c} (cd/A) | | ηₚ (lm/W) | |
| Anode structure (nm) | (nm) | J = 20 | J = 100 | J = 20 | J = 100 | J = 20 | J = 100 | J = 20 | J = 100 |
| Ag (25) | Alq (10) | No Light | No Light | 7.0 | N/A | 0 | 0 | 0 | 0 |
| Ag (25) | C60 (10) | No Light | No Light | N/A | 7.1 | 0 | 0 | 0 | 0 |
| Ag (25)/C60 (3) | Alq (10) | 404 | 7720 | 9.5 | 13.6 | 2.02 | 7.72 | 0.67 | 1.78 |
| Ag (25)/C60 (3) | C60 (10) | 318 | 3600 | 6.7 | 8.8 | 1.59 | 3.60 | 0.75 | 1.29 |

TABLE III
Device characteristics of inverted top-emission OLEDs with various Ag/fullerene
anode structures. The OLEDs were constructed follows a stacking sequence: glass
substrate/cathode/ETL/EL/HTL/HIL/Anode. The materials for HIL, HTL, EL and
cathode are CuPc (15 nm), NPB (45 nm), Alq (25 nm) and LiF (1.5 nm)/Al (75 nm),
respectively. Alq and C60 were used as ETL to test the OLED performance.
The luminance, driving voltage, current efficiency η_{c} (cd/A) and power
efficiency ηₚ (lm/W) were listed at two are current densities
J = 20 mA/cm² and 100 mA/cm², respectively.

| Device structure | | Luminance | | | | | | | |
|---|---|---|---|---|---|---|---|---|---|
| Anode structure | | (cd/m²) | | Voltage (V) | | η_{c} (cd/A) | | ηₚ (lm/W) | |
| (nm) | ETL (nm) | J = 20 | J = 100 | J = 20 | J = 100 | J = 20 | J = 100 | J = 20 | J = 100 |
| Ag (30)/C60 (3) | Alq (15) | 902 | 2790 | 13.6 | 15.1 | 4.51 | 2.79 | 1.04 | 0.58 |
| Ag (30)/C60 (3) | C60 (15) | 334 | 960 | 12.8 | 14.0 | 1.67 | 0.96 | 0.41 | 0.21 |

TABLE IV
Device characteristics of inverted top-emission OLEDs with various Au/fullerene
anode structures. The devices were constructed follows a stacking sequence: glass
substrate/cathode/ETL/EL/HTL/HIL/Anode. The materials for HIL, HTL, EL and
cathode are CuPc (15 nm), NPB (45 nm), Alq (25 nm) and LiF (1.5 nm)/Al (120 nm),
respectively. Alq and C60 were used as ETL to test the OLED performance.
The luminance, driving voltage, current efficiency η_{c} (cd/A) and
power efficiency ηₚ (lm/W) were listed at two are current densities
J = 20 mA/cm² and 100 mA/cm², respectively.

| | | Luminance | | | | | | | |
|---|---|---|---|---|---|---|---|---|---|
| Device structure | | (cd/m²) | | Voltage (V) | | η_{c} (cd/A) | | ηₚ (lm/W) | |
| Anode structure (nm) | HIL (nm) | J = 20 | J = 100 | J = 20 | J = 100 | J = 20 | J = 100 | J = 20 | J = 100 |
| Au (30)/C60 (3) | CuPc(0) | 3.16 | 16.04 | 19.8 | 22.5 | 0.0158 | 0.0160 | 0.00251 | 0.00223 |
| Au (30)/C60 (3) | CuPc (15) | 10.76 | 63.1 | 12.1 | 14.4 | 0.0538 | 0.0631 | 0.0140 | 0.0138 |

TABLE V
Device characteristics of OLEDs with various Au/fullerene anode structures.
Here the fullerene layer is a mixture of C60 and CuPc with various C60 concentration
varied from 0 wt. % to 100 wt. %. The OLEDs were constructed follows a
stacking sequence: glass substrate/Anode/HTL/EL/ETL/cathode.
The materials for HTL, EL, ETL and cathode are NPB (45 nm), Alq (25 nm),
Alq (15 nm) and LiF (1 nm)/Al (100 nm), respectively. The luminance,
driving voltage, current efficiency η_{c} (cd/A) and power efficiency
ηₚ (lm/W) were listed at two are current densities J = 20 mA/cm²
and 100 mA/cm², respectively.

| | | | | |
|---|---|---|---|---|
| | Luminance | | | |
| Anode structure | (cd/m²) | Voltage(V) | η_{c}(cd/A) | ηₚ (lm/W) |

| Au(25 nm)/(C60:CuPc)(25 nm) | J = 20 | J = 100 | J = 20 | J = 100 | J = 20 | J = 100 | J = 20 | J = 100 |
|---|---|---|---|---|---|---|---|---|
| 0 wt. % C60 | 743 | 3150 | 18.1 | 20.4 | 3.72 | 3.15 | 0.64 | 0.48 |
| 7 wt. % C60 | 1211 | 5352 | 15.2 | 17.3 | 6.06 | 5.35 | 1.25 | 0.97 |
| 14 wt. % C60 | 1708 | 8168 | 12.6 | 14.8 | 8.54 | 8.17 | 2.13 | 1.73 |
| 20 wt. % C60 | 1542 | 7579 | 10.7 | 13 | 7.71 | 7.58 | 2.26 | 1.83 |
| 30 wt. % C60 | 1713 | 8668 | 8.6 | 10.7 | 8.57 | 8.67 | 3.13 | 2.54 |
| 50 wt. % C60 | 1377 | 6593 | 12.7 | 14.9 | 6.89 | 6.59 | 1.70 | 1.39 |
| 80 wt. % C60 | 891.3 | 4477 | 12.1 | 14.7 | 4.46 | 4.48 | 1.16 | 0.96 |
| 100 wt. % C60 | 149 | 733 | 20.8 | 23.3 | 0.75 | 0.73 | 0.11 | 0.10 |

TABLE VI
Device characteristics of OLEDs with various Ag/fullerene anode structures.
Here the fullerene layer is a mixture of C60 and CuPc with various C60
concentration varied from 0 wt. % to 50 wt. %. The OLEDs were constructed
follows a stacking sequence: glass substrate/Anode/HTL/EL/ETL/cathode.
The materials for HTL, EL, ETL and cathode are NPB (45 nm), Alq (25 nm),
Alq (15 nm) and LiF (1 nm)/Al (100 nm), respectively. The luminance,
driving voltage, current efficiency η_{c} (cd/A) and power efficiency
ηₚ (lm/W) were listed at two are current densities J = 20
mA/cm² and 100 mA/cm², respectively.

| | Luminance | | | | | | | |
|---|---|---|---|---|---|---|---|---|
| Anode structure | (cd/m²) | | Voltage(V) | | η_{c}(cd/A) | | ηₚ (lm/W) | |
| Ag(25 nm)/(C60:CuPc)(25 nm) | J = 20 | J = 100 | J = 20 | J = 100 | J = 20 | J = 100 | J = 20 | J = 100 |
| 0 wt % C60 | 0.00 | 0.00 | 7.0 | — | 0.00 | 0.00 | 0.00 | 0.00 |
| 10 wt. % C60 | 1265 | 6106 | 15.3 | 17.3 | 6.33 | 6.11 | 1.30 | 1.11 |
| 30 wt. % C60 | 1480 | 7331 | 13.9 | 15.8 | 7.40 | 7.33 | 1.67 | 1.46 |
| 50 wt. % C60 | 0 | 6.83 | 4.2 | 6.6 | 0.00 | 0.01 | 0.00 | 0.00 |

TABLE VII
Device characteristics of OLEDs with Au:C60 anode. The OLEDs were constructed
follows a stacking sequence: glass substrate/Anode/HTL/EL/ETL/cathode.
The materials for HTL, EL, ETL and cathode are CuPc(25 nm)/NPB (45 nm),
Alq (25 nm), Alq (15 nm) and LiF (1.5 nm)/Al (100 nm), respectively. The luminance,
driving voltage, current efficiency η_{c} (cd/A) and power efficiency ηₚ
(lm/W) were listed at two are current densities J = 20 mA/cm² and
100 mA/cm², respectively.

| | Luminance | | | | | | | |
|---|---|---|---|---|---|---|---|---|
| Anode structure | (cd/m²) | | Voltage(V) | | η_{c}(cd/A) | | ηₚ (lm/W) | |
| Au:C60 mixture (20 nm) | J = 20 | J = 100 | J = 20 | J = 100 | J = 20 | J = 100 | J = 20 | J = 100 |
| 0 wt % C60 | 286 | 1490 | 19.3 | 21.1 | 1.43 | 1.49 | 0.23 | 0.22 |
| 1 wt % C60 | 270 | 1340 | 10.0 | 11.7 | 1.35 | 1.34 | 0.42 | 0.36 |
| 9 wt % C60 | 312 | 1610 | 5.6 | 6.8 | 1.56 | 1.61 | 0.88 | 0.74 |

Therefore what is claimed is:

1. A layered electrically conductive material/fullerene anode structure comprising:
a) a substrate and a first layer comprising fullerenes located on a surface of the substrate; and
b) a second layer comprising an electrically conductive material located on a top surface of said first layer, the thickness of the first layer being selected so that the layered electrically conductive material/fullerene anode structure exhibits hole injection behavior across the first and second layers.

2. The layered structure according to claim 1 wherein said fullerenes are selected from the group consisting of C60, C70, carbon nanotubes and combinations thereof.

3. The layered structure according to claim 1 wherein said first layer comprising fullerenes includes at least one further constituent mixed with said fullerenes selected from the group consisting of organic molecules, inorganic materials, conducting polymers, polymeric fullerenes, fullerenes chemically bonded to conducting polymers, and combinations thereof.

4. The layered structure according to claim 3 wherein said organic molecules include CuPc and m-MTDATA.

5. The layered structure according to claim 2 wherein said first layer has a pre-selected thickness in a range from about 1 nm to about 10 nm.

6. The layered structure according to claim 3 wherein said first layer has a pre-selected thickness in a range from about 10 nm to about 60 nm.

7. The layered structure according to claim 1 wherein said electrically conductive material is a metal selected from the group consisting of Al, Cr, Cu, Ag, Au, Ni, Fe, Ni, W, Mo, Co and metal alloys.

8. The layered structure according to claim 1 wherein said electrically conductive material is gold (Au).

9. The layered structure according to claim 1 wherein said electrically conductive material is silver (Ag).

10. The layered structure according to claim 1 wherein said electrically conductive material includes at least two metal layers selected from the group consisting of Cr/Au, Ag/Au, Cr/Ag, Cr/Pt, Cr/Ni, Cr/Ag/Au, and Cr/Cu/Au.

11. The layered structure according to claim 1 wherein said electrically conductive material is a multilayered conducting material including at least two conducting layers, a first conducting layer being selected from the group consisting of conducting metal oxides, and at least a second conducting layer being selected from the group consisting of metals.

12. The layered structure according to claim 11 wherein said electrically conducting metal oxides are selected from the group consisting of tin oxides and indium tin oxides (ITO), and where said metal is selected from the group consisting of Au, Ag, Ni, and metal/metal bilayers or metal oxide/metal multilayers selected from the group consisting of Cr/Ag, Cr/Pt, SiO₂/Au, SiO₂/Ag, Si/SiO₂/Au, and Si/SiO₂/Ag.

13. The layered structure according to claim 1 wherein said electrically conductive material is a mixture of metal and fullerenes.

14. The layered structure according to claim 13 wherein said mixture of metal and fullerenes is a mixture of Au and C60.

15. The layered structure according to claim 1 wherein said substrate is a hole transport layer of a device selected from the group consisting of optoelectronic devices and electronic devices.

16. The layered structure according to claim 15 wherein said optoelectronic devices are selected from the group consisting of light-emitting diodes, solar cells and photodetectors.

17. The layered structure according to claim 15 wherein said electronic devices are selected from the group consisting of field-effect transistors and tunneling diodes.

18. A light-emitting device, comprising:
a) an electrically conductive layered metal/fullerene anode electrode including a metal layer formed on a substrate and a layer including fullerenes formed on the metal layer;
b) a hole transport layer located on the fullerene layer;
c) a layer of electroluminescent material located on the hole transport layer; and
d) an electrically conductive layer defining a cathode electrode layer on the layer of a electroluminescent material, and wherein one or both of the electrically conductive layered metal/fullerene anode electrode and the cathode electrode layer is semi-transparent so that the light emitted from the layer of electroluminescent material exits the device.

19. The light-emitting device of claim 18 including an electron transport layer located between the cathode electrode layer and the layer of electroluminescent material.

20. The light-emitting device of claim 18 including a hole injection layer interposed between the hole transport layer and the fullerene layer.

21. The light-emitting device of claim 19 including a hole injection layer interposed between the hole transport layer and the fullerene layer.

22. The light-emitting device of claim 18 wherein said metal of the electrically conductive layered metal/fullerene anode electrode comprises a high work function metal.

23. The light-emitting device of claim 22 wherein said high work function metal is selected from the group consisting of Ni, Cu, Pd, Pt, Mo and W.

24. The light-emitting device of claim 22 wherein said high work function metal is selected from the group consisting of noble metals.

25. The light-emitting device of claim 24 therein said noble metals are selected from the group consisting of Au and Ag.

26. The light-emitting device of claim 18 wherein said metal of the electrically conductive layered metal/fullerene anode electrode comprises a mixture of metal and fullerene.

27. The light-emitting device of claim 26 therein said mixture of metal and fullerene is a mixture of Au and C60.

28. The light-emitting device of claim 18 wherein said metal layer of the electrically conductive layered metal/fullerene anode electrode comprises electrically conductive bilayers.

29. The light-emitting device of claim 28 wherein said electrically conductive bilayers are selected from the group consisting of Cr/Au, Cr/Ni, Cr/Pt, Cr/Ag, Si/Au, ITO/Au, Cu/Au, ITO/Ni, and ITO/Ag.

30. The light-emitting device of claim 18 wherein said fullerenes are selected from the group consisting of C60, C70, and mixtures thereof.

31. The light-emitting device of claim 18 wherein a thickness of said fullerene layer is in a range 1 nm to 10 nm.

32. The light-emitting device of claim 20 wherein the hole injection layer is comprised of highly conductive organic molecules.

33. The light-emitting device of claim 32 wherein the highly conductive organic molecules are CuPc, and wherein said hole injection layer has a thickness in a range from about 5 nm to about 50 nm.

34. The light-emitting device of claim 18 wherein said fullerene layer of the layered metal/fullerene anode comprises a mixture of fullerenes, conductive organic molecules, polymers, or combinations thereof.

35. The light-emitting device of claim 34 wherein said mixture is C60:CuPc.

36. The light-emitting device of claim 35 wherein a thickness of said C60:CuPc mixture is in a range from 5 nm to about 50 nm.

37. The light-emitting device of claim 35 wherein said C60:CuPc mixture includes said C60 present in a range from about 10 wt. % to about 50 wt. %.

38. The light-emitting device of claim 34 wherein said mixture is C60:m-MTDATA.

39. The light-emitting device of claim 38 wherein a thickness of said C60:m-MTDATA mixture is in a range from about 5 nm to about 50 nm.

40. The light-emitting device of claim 38 wherein said C60:m-MTDATA mixture includes said C60 present in a range from about 10 wt. % to about 50 wt. %.

41. The light-emitting device of claim 18 including a dielectric layer interposed between the metal layer and the substrate.

42. The light-emitting device of claim 41 wherein said dielectric layer is a phosphor layer which can be excited by light emitted from the electroluminescent layer.

43. The light-emitting device of claim 18 wherein said electrically conductive layered metal/fullerene anode electrode is semi-transparent to allow light produced in the layer of electroluminescent material to exit the device through the electrically conductive layered metal/fullerene anode electrode, and wherein the cathode electrode layer is highly reflective to reflect light produced in the layer of electroluminescent material back through the device and out through the electrically conductive layered metal/fullerene anode electrode.

44. The light-emitting device of claim 18 wherein said cathode electrode layer is semi-transparent to allow light produced in the layer of electroluminescent material to exit the device through the cathode electrode layer, and wherein said electrically conductive layered metal/fullerene anode electrode includes a highly reflective constituent to reflect light produced in the layer of electroluminescent material back through the device and out through the cathode electrode layer.

45. The light-emitting device of claim 18 including a power supply for applying a voltage across the electrically conductive layered metal/fullerene anode electrode and the cathode electrode layer.
